(19) United States
(12) Patent Application Publication
(10) Pub. No.: US 2010/0290945 A1
(43) Pub. Date: Nov. 18, 2010

(54) SOLUTION BASED ZIRCONIUM PRECURSORS FOR ATOMIC LAYER DEPOSITION

(76) Inventors: Ce MA, San Diego, CA (US); Kee-Chan Kim, Carlsbad, CA (US); Graham Anthony McFarlane, Carlsbad, CA (US)

Correspondence Address: The BOC Group, Inc., 575 MOUNTAIN AVENUE, MURRAY HILL, NJ, 07974-2082, US

(21) Appl. No.: 12/465,085

(22) Filed: May 13, 2009

(51) Int. Cl. C23C 16/06; C07F 7/00; C01G 25/02; C01B 21/076; C22C 16/00

(52) U.S. Cl. 420/422; 427/255.36; 427/255.394; 427/255.28; 556/52; 423/608; 423/411

(57) ABSTRACT

Oxygen free, solution based zirconium precursors for use in ALD processes are disclosed for growing ZrO₂ or other Zr compound films in a self-limiting and conformal manner. An oxygen free, solution based ALD precursor of (t-BuCp)₂ZrMC₂ is particular useful for depositing ZrO₂ or other Zr compound films.

### RELATED APPLICATIONS

The solution based ALD precursors of the present invention are related to other work carried out by the inventors and assignee of this application. In particular, U.S. Ser. No. 11/400,904 relates to methods and apparatus of using solution based precursors for ALD. U.S. Ser. No. 12/396,806 relates to methods and apparatus of using solution based precursors for ALD. U.S. Ser. No. 12/373,913 relates to methods of using solution based precursors for ALD. U.S. Ser. No. 12/374,066 relates to methods and apparatus for the vaporization and delivery of solution based precursors for ALD. U.S. Ser. No. 12/261,169 relates to solution based lanthanum precursors for ALD.

### FIELD OF THE INVENTION

The present invention relates to new and useful solution based precursors for atomic layer deposition.

### BACKGROUND OF THE INVENTION

Atomic layer deposition (ALD) is an enabling technology for advanced thin-film deposition, offering exceptional thickness control and step coverage. In addition, ALD is an enabling technique that will provide the next generation conductor barrier layers, high-k gate dielectric layers, high-k capacitance layers, capping layers, and metallic gate electrodes in silicon wafer processes. ALD-grown high-k and metal gate layers have shown advantages over physical vapor deposition and chemical vapor deposition processes. ALD has also been applied in other electronics industries, such as flat panel display, compound semiconductor, magnetic and optical storage, solar cell, nanotechnology and nanomaterials. ALD is used to build ultra thin and highly conformal layers of metal, oxide, nitride, and others one monolayer at a time in a cyclic deposition process. Oxides and nitrides of many main group metal elements and transition metal elements, such as aluminum, titanium, zirconium, hafnium, and tantalum, have been produced by ALD processes using oxidation or nitridation reactions. Pure metallic layers, such as Ru, Cu, Ta, and others may also be deposited using ALD processes through reduction or combustion reactions.

The widespread adoption of ALD processes faces challenges in terms of a restricted selection of suitable precursors, low wafer throughput, and low chemical utilization. Many ALD precursors useful in HKMG exist in the solid phase with relatively low volatility. To meet these challenges, the present invention develops a solution-precursor-based ALD technology called Flex-ALD™. With solution-based precursor technology, ALD precursor selection is considerably broadened to include low-volatility solid precursors, wafer throughput is increased with higher film growth rates, and chemical utilization is improved via the use of dilute chemistries. In addition, liquid injection with vapor pulses provides consistent precursor dosage.

A typical ALD process uses sequential precursor gas pulses to deposit a film one layer at a time. In particular, a first precursor gas is introduced into a process chamber and produces a monolayer by reaction at surface of a substrate in the chamber. A second precursor is then introduced to react with the first precursor and form a monolayer of film made up of components of both the first precursor and second precursor, on the substrate. Each pair of pulses (one cycle) produces one monolayer or less of film allowing for very accurate control of the final film thickness based on the number of deposition cycles performed.

As semiconductor devices continue to get more densely packed with devices, channel lengths also have to be made smaller and smaller. For future electronic device technologies, it will be necessary to replace SiO₂ and SiON gate dielectrics with ultra thin high-k oxides having effective oxide thickness (EOT) less than 1.5 nm. Preferably, high-k materials should have high band gaps and band offsets, high k values, good stability on silicon, minimal SiO₂ interface layer, and high quality interfaces on substrates. Amorphous or high crystalline temperature films are also desirable.

Zirconium oxide (ZrO₂) is a promising high-k dielectric material for use in advanced CMOS devices because it has a relatively stable dielectric constant (30-40). ZrO₂ has been found to be a better gate dielectric for III-V high electron mobility channels by reducing the interfacial layer while maintaining the effective high-k value. In addition, ZrO₂ can be used as memory capacitance material for the 32 nm DRAM technology node and beyond.

ALD is a preferred method of depositing ultra thin layers of ZrO₂ and are generally based upon the use of amide or Cp based liquid precursors. However, using standard ALD deposition techniques for these conventional precursors requires high source temperatures which can lead to premature precursor decomposition. To overcome this, direct injection of amide based precursors, such as TEMAZ or TMAZr can be done, but the molecules are not stable at the deposition temperature which can contribute to CVD-like self growth with resultant loss of quality and controllability of uniform deposition.

There remains a need in the art for improvements to solvent based ALD precursors.

### SUMMARY OF THE PRESENT INVENTION

The present invention provides improved solvent based precursor formulations. In particular, the present invention provides solution based, oxygen free zirconium ALD precursors for growing ZrO₂ or other Zr compound films in a self-limiting and conformal manner.

### DETAILED DESCRIPTION OF THE INVENTION

The present invention provides Zr based materials for use as ALD precursors. Initially, a new class of cyclopentadienyl (Cp) based precursors containing a metal-oxygen bond in addition to a metal-carbon bond were evaluated. These oxygen containing precursors exhibit high decomposition temperatures, but they have not proved to be ideal ALD materials. One reason for this is that most oxygen free Cp precursors are in the solid state at room temperature and therefore require high source temperatures.

In particular, the oxygen containing Cp complexes, TEMAZ and (MeCp)₂Zr(OMe)(Me) were reviewed. TEMAZ was found to be thermally unstable and (MeCp)₂Zr(OMe)(Me) exhibited self growth. It is believed that the presence of oxygen in the precursor may intrinsically lead to the self growth.

In light of the above problems experienced with oxygen containing precursors, the present invention relates to the use of oxygen free Cp zirconium precursors for forming true ALD films of ZrO₂. In particular, the present invention relates to oxygen free Cp Zr complexes having one of the following formulas: (MeCp)₂ZrMe₂; (Me₅Cp)₂ZrMe₂; or (t-BuCp)₂ZrMe₂; each of which will be discussed separately below.

The single branched Cp ring precursor (MeCp)₂ZrMe₂ was not stable and therefore did not prove to be useful as an ALD precursor. The methyl saturated Cp ring precursor (Me₅Cp)₂ZrMe₂ exhibited poor solubility and therefore also failed to be useful as an ALD precursor.

The best candidate for an oxygen free solution based ALD precursor was (t-BuCp)₂ZrMe₂. This solid precursor may be dissolved in purified solvents, such as n-octane, at room temperature with a solubility of greater than 0.2M. Both the solid precursor and the solvent are oxygen free. Solution concentration for ALD applications is preferably from 0.05M to 0.15M and more preferably 0.1M.

The solution based precursor; i.e. (t-BuCp)₂ZrMe₂ dissolved in a solvent, may be delivered at room temperature to a point-of-use vaporizer by a direct liquid injection method. The fully vaporized solution precursors are then pulsed into a deposition chamber using inert gas switches to create an ideal square wave of ALD precursor delivery. The vaporizer temperature is preferably between 150° C. and 250° C. and more preferably 190° C.

Using the precursor formulation of the present invention, ZrO₂ and other Zr compound films are deposited in a hot wall chamber that contains in situ growth monitor using a quartz crystal microbalance. The oxygen precursors for ZrO₂ films are water vapor, ozone or other oxygen containing gas or vapor. In particular, the oxygen precursor can be water vapor, O₂, O₃, N₂O, NO, CO, CO₂, CH₃OH, C₂H₅OH, other alcohols, other acids and oxidants. The preferred oxidant precursor is water vapor at room temperature from a de-ionized water vapor source. The film growth temperature is preferably from 180° C. to 280° C. and more preferably from 200° C to 240° C. Saturation of growth was tested by increasing either Zr precursor dose or water vapor dose. This indicated that the growth was true self-limiting ALD growth with no self growth.

In addition, zirconium nitride films can be produced according to the present invention by using a nitrogen containing reactant such as NH₃, N₂H₄, amines, etc as the second precursor. Similarly, metal zirconium ALD films can be formed by using hydrogen, hydrogen atoms or other reducing agents as the second precursor.

Other solvents and additives may be included in the zirconium precursor solution. However, these solvents and additives must not interfere with the ALD process either in the gas phase or on the substrate surface. In addition, the solvents and additives should be thermally robust without any decomposition at ALD processing temperatures. Hydrocarbons are preferred as primary solvents to dissolve ALD precursors by means of agitation or ultrasonic mixing if necessary. Hydrocarbons are chemically inert and compatible with the precursors and do not compete with the precursors for reaction sites on the substrate surface. The boiling point of the solvents should be high enough to match the volatility of the solute in order to avoid particle generation during the vaporization process.

The precursors of the present invention provide several advantages, including being able to employ solid precursors for liquid solution based ALD processes. By using such chemistries, a low thermal budget room temperature delivery is possible and thereby overcomes thermal decomposition problems associated with standard liquid precursors, such as TEMAZ. The Cp based solution precursors of the present invention are thermally stable and employing oxygen free solution chemistries eliminates the self growth that occurs with oxygen containing Cp precursors.

The precursors of the present invention are useful for several applications. In particular, the precursors of the present invention may be used for forming high-k gate dielectric layers for Si, Ge, and C based group IV elemental semiconductors or for forming high-k gate dielectric layers for InGaAs, AlGaAs, and other III-V high electron mobility semiconductors. In addition, the precursors of the present invention are useful for forming high-k capacitors for DRAM, flash and ferroelectric memory devices. The precursors of the present invention can also be useful as Zr-based catalysts for gas purification, organic synthesis, fuel cell membranes and chemical detectors, in yttrium stabilized zirconia (YZT) solid anode materials in fuel cells, or as super cooled Zr based alloys that remain in liquid state at about 100° K.

It is anticipated that other embodiments and variations of the present invention will become readily apparent to the skilled artisan in the light of the foregoing description, and it is intended that such embodiments and variations likewise be included within the scope of the invention as set out in the appended claims.

What is claimed:

1. A precursor for atomic layer deposition comprising an oxygen free zirconium cyclopentadienyl compound

2. The precursor of claim 1 wherein the compound has the formula:
(R₁R₂R₃R₄R₅Cp)₂MR₆R₇
wherein R₁, R₂, R₃, R₄, R₅, R₆ and R₇ are H or a hydrocarbon having the formula CₙHₘ, wherein n=1 to 10 and m=1 to 2n+1, Cp is cyclopentadienyl and M is a Group IV element.

3. The precursor of claim 2 comprising (t-BuCp)₂ZrMe₂.

4. The precursor of claim 3 dissolved in a solvent to form a precursor solution.

5. The precursor of claim 4 wherein the solvent is n-octane and the precursor solution has a concentration of 0.05M to 0.15M.

6. The precursor of claim 5 wherein the concentration is 0.1M.

7. A zirconium oxide film deposited by atomic layer deposition using a precursor comprising an oxygen free zirconium cyclopentadienyl compound.

8. The film of claim 7 wherein the precursor is (t-BuCp)₂ZrMe₂.

9. A zirconium nitride film deposited by atomic layer deposition using a precursor comprising an oxygen free zirconium cyclopentadienyl compound.

10. The film of claim 9 wherein the precursor is (t-BuCp)₂ZrMe₂.

11. A zirconium film deposited by atomic layer deposition using a precursor comprising an oxygen free zirconium cyclopentadienyl compound.

12. The film of claim 11 wherein the precursor is (t-BuCp)₂ZrMe₂.

13. A method of atomic layer deposition comprising
introducing a first precursor comprising an oxygen free zirconium cyclopentadienyl compound dissolved in a solvent to a vaporizer;
vaporizing the first precursor solution in the vaporizer;
delivering the vaporized first precursor to a deposition chamber;
forming a monolayer of a zirconium containing molecule by surface reaction on a substrate;
purging the deposition chamber;
introducing a second precursor comprising an oxygen containing compound to the deposition chamber;
forming one monolayer of zirconium oxide by surface reaction on the substrate; and
repeating the steps to produce a zirconium oxide film of predetermined thickness on the substrate.

14. The method of claim 13 wherein delivering the vaporized first precursor comprises delivering the first precursor in an ideal square wave form.

15. The method of claim 13 wherein introducing the second precursor comprises delivering the second precursor in an ideal square wave form.

16. The method of claim 13 wherein the vaporizer temperature is between 150° C. and 250° C. and the deposition temperature is between 180° C. and 280° C.

17. The method of claim 16 wherein the vaporizer temperature is 190° C. and the deposition temperature is between 200° C. and 240° C.

18. The method of claim 13 wherein the second precursor is water vapor, O₂, O₃, N₂O, NO, CO, CO₂, CH₃OH, C₂H₅OH, an alcohol, an acid, or an oxidant.

19. A method of atomic layer deposition comprising
introducing a first precursor comprising an oxygen free zirconium cyclopentadienyl compound dissolved in a solvent to a vaporizer;
vaporizing the first precursor solution in the vaporizer;
delivering the vaporized first precursor to a deposition chamber;
forming monolayer of a zirconium containing molecule by surface reaction on a substrate;
purging the deposition chamber;
introducing a second precursor comprising a nitrogen containing compound to the deposition chamber;
forming one monolayer of zirconium nitride by surface reaction on the substrate; and
repeating the steps to produce a zirconium nitride film of predetermined thickness on the substrate.

20. The method of claim 19 wherein delivering the vaporized first precursor comprises delivering the first precursor in an ideal square wave form.

21. The method of claim 19 wherein introducing the second precursor comprises delivering the second precursor in an ideal square wave form.

22. The method of claim 19 wherein second precursor is NH₃, N₂H₄, or an amine.

23. A method of atomic layer deposition comprising
introducing a first precursor comprising an oxygen free zirconium cyclopentadienyl compound dissolved in a solvent to a vaporizer;
vaporizing the first precursor solution in the vaporizer;
delivering the vaporized first precursor to a deposition chamber;
forming monolayer of a zirconium containing molecule by surface reaction on a substrate;
purging the deposition chamber;
introducing a second precursor comprising a reducing agent to the deposition chamber;
forming one monolayer of zirconium metal by surface reaction on the substrate; and
repeating the steps to produce a zirconium metal film of predetermined thickness on the substrate.

24. The method of claim 23 wherein delivering the vaporized first precursor comprises delivering the first precursor in an ideal square wave form.

25. The method of claim 23 wherein introducing the second precursor comprises delivering the second precursor in an ideal square wave form.

26. The method of claim 23 wherein the reducing agent is hydrogen or hydrogen atoms.
